(19) United States
(12) Patent Application Publication
(10) Pub. No.: US 2014/0008635 A1
(43) Pub. Date: Jan. 9, 2014

(54) ORGANIC ELECTROLUMINESCENCE ELEMENT

(71) Applicants: Tomohiro Kitagaki, Osaka (JP); Takeyuki Yamaki, Nara (JP); Masahiro Nakamura, Eindhoven (NL); Masahito Yamana, Hyogo (JP)

(72) Inventors: Tomohiro Kitagaki, Osaka (JP); Takeyuki Yamaki, Nara (JP); Masahiro Nakamura, Eindhoven (NL); Masahito Yamana, Hyogo (JP)

(73) Assignee: PANASONIC CORPORATION, Osaka (JP)

(21) Appl. No.: 14/007,091

(22) PCT Filed: Feb. 17, 2012
(86) PCT No.: PCT/JP2012/001045

§ 371 Date: Sep. 24, 2013

(30) Foreign Application Priority Data
Apr. 5, 2011 (JP) 2011-083316

(51) Int. Cl. H01L 51/52

(52) U.S. Cl. CPC H01L 51/5268
USPC 257/40

(57) ABSTRACT

An organic electroluminescence element includes: an organic layer which is located between a first electrode layer and a second electrode layer; a light extraction layer which is located on at least one surface of the first electrode layer and the second electrode layer so that directivity of light is changed; and a substrate located on the light extraction layer. The light extraction layer has a base material and a light-scattering particle of 1 to 5 wt. % of the base material. The above configuration allows a light extraction layer to be a single layer and makes it difficult to form a gap at an interface between a base material and light-scattering particles, so that light extraction efficiency can be enhanced.

### TECHNICAL FIELD

The present invention relates to an organic electroluminescence element which has a light extraction layer.

### BACKGROUND ART

In an electroluminescence (EL) device, a light emitting layer is formed on a transparent substrate so as to be interposed between an anode and a cathode. When a voltage is applied between the electrodes, light is emitted by exciters generated by recombination of holes and electrons injected as carriers to the light emitting layer. EL devices are generally classified into organic EL devices in which an organic substance is used as a fluorescent substance of a light emitting layer, and inorganic EL devices in which an inorganic substance is used as a fluorescent substance of a light emitting layer. In particular, organic EL devices are capable of emitting light of high luminance with a low voltage, and various colors of emitted light are obtained therefrom depending on the types of fluorescent substances. In addition, it is easy to manufacture organic EL devices as planar light emitting panels, and thus organic EL devices are used as various display devices and backlights. Furthermore, in recent years, organic EL devices designed for high luminance have been realized, and attention has been paid to use of these organic EL devices for lighting apparatuses.

FIG. 3 shows a cross-sectional configuration of a common organic EL device. In an organic EL element 101, a translucent anode layer 102 is located on a translucent substrate 106, and an organic layer 104 which is made up of a hole transport layer 142, a light emitting layer 141, and an electron transport layer 143 is located on the anode layer 102. A light reflective cathode layer 103 is located on the organic layer 104. When a voltage is applied between the anode layer 102 and the cathode layer 103, light, which is emitted by the organic layer 104, passes through the anode layer 102 and the substrate 106 and then is taken out.

When light propagates from a medium with a high refractive index to a medium with a low refractive index, a critical angle at an interface therebetween is determined based on the refractive index between the media in accordance with Snell's law, and light which has a higher incident angle than the critical angle is totally reflected at the interface, confined to the medium with the high refractive index, and lost as guided light. Glass is widely used for the substrate 106, which is used as the common organic EL element 101, from a standpoint of excellent transparency, intensity, low cost, gas barrier layer, chemical resistance, heat resistance, etc., and a refractive index of a general soda-lime glass or the like is around 1.52. Moreover, Indium Tin Oxide (ITO), which is indium oxide doped with tin oxide, or Indium Zinc Oxide (IZO) is widely used for the anode layer 102 due to its excellent transparency and electric conductivity. Although refractive indexes of ITO and IZO change in accordance with a composition, a film formation method, a crystal construction, or the like, ITO and IZO have extremely the high refractive indexes of approximately 1.7 to 2.3 and approximately 1.9 to 2.4, respectively.

Mainly, refractive indexes of materials such as emitting materials constituting the light emitting layer 141, the hole transport layer 142, the electron transporting material 143, or the like, which is used for the organic layer 104, are approximately 1.6 to 2.0, respectively. That is to say, in the organic EL element 101, a magnitude relation among the refractive indexes of the respective layers is expressed as follows: atmosphere<the substrate<the organic layer<the anode. Accordingly, light which is outputted from an emitting source of the light emitting layer 141 in the organic EL element 101 at a high angle is totally reflected at an interface between a substrate 106 and an outside of the element (the atmosphere) and an interface between an anode 102 and the substrate 106, so that sometimes it is not taken out to the outside of the element as an effective light.

Thus, there is a known organic EL element which enhances a light usage efficiency of light emitted from the light emitting layer 141 by providing a light extraction layer, which is made up of a layer having light-scattering function, or the like between the substrate 106 and the anode layer 102 to take out the light (refer to Japanese Laid-Open Patent Publication No. 2006-286616, for example).

In the organic EL element described in Japanese Laid-Open Patent Publication No. 2006-286616, a light-scattering particle layer which includes light-scattering particles is used as a part of the light extraction layer. However, a surface of the light-scattering particle layer has an irregular surface due to a presence of the light-scattering particles. When the surface is irregular, the anode, the organic layer, and the cathode cannot be uniformly layered in thickness, so that a smoothing layer is formed on an upper surface side of the light-scattering particle layer to smooth the upper surface side. However, when the smoothing layer is layered on the light extraction layer, a gap sometimes occurs at an interface between the light-scattering particle layer and the smoothing layer, and due to the gap, the light extraction layer does not function sufficiently, so that there is a problem that a light extraction efficiency may decrease.

### DISCLOSURE OF THE INVENTION

The present invention is to solve the problem described above, and an object of the present invention is to provide an organic EL element which allows a light extraction layer to be a single layer and prevents an arising of a gap at an interface between a base material and light-scattering particles, so that light extraction efficiency can be enhanced.

To solve the above problem, an organic electroluminescence element includes: an organic layer which is located between a first electrode layer and a second electrode layer; a light extraction layer which is located on at least one surface of the first electrode layer and the second electrode layer so that directivity of light is changed; and a substrate located on the light extraction layer, wherein the light extraction layer has a base material which constitutes the light extraction layer and a light-scattering particle of 1 to 5 wt. % of the base material.

It is preferable that in the organic electroluminescence element, a particle diameter of the light-scattering particle is 0.1 to 10 μm.

It is preferable that in the organic electroluminescence element, the light-scattering particle is a particle whose shape differs in a long axis direction and a short axis direction.

It is preferable that the organic electroluminescence element, the light-scattering particle has an irregular configuration on its surface.

It is preferable that the organic electroluminescence element, a difference between a refractive index of the base material constituting the light extraction layer and a refractive index of the light-scattering particle is 0.15 to 0.45.

It is preferable that the organic electroluminescence element, a refractive index of the base material constituting the light extraction layer and a refractive index of the first electrode layer or the second electrode layer contacting the light extraction layer is substantially equal to each other.

According to the present invention, the light extraction layer includes the light-scattering particle of 1 to 5 wt. % of the base material, so that the light extraction efficiency can be enhanced efficiently even by the single layer. Moreover when the light-scattering particle of 1 to 5 wt. % is included, the gap at the interface between the base material and the light-scattering particles is difficult to form, so that the light extraction efficiency can be further enhanced.

### BRIEF DESCRIPTION OF THE DRAWINGS

FIG. 1 is a side sectional view of an organic electroluminescence element according to a preferred embodiment of the present invention.

FIG. 2A is a diagram showing a microscope photograph of a surface of a light extraction layer which is made by applying light-scattering particles of 5 wt. % of a base material on a substrate in the organic electroluminescence element of FIG. 1.

FIG. 2B, which is a comparison example of the organic electroluminescence element in FIG. 1, is a diagram showing a microscope photograph of a surface of a light extraction layer which is made by applying the light-scattering particles of 7.5 wt. % of the base material on the substrate.

FIG. 3 is a side sectional view of a conventional organic electroluminescence element.

### DESCRIPTION OF THE PREFERRED EMBODIMENTS

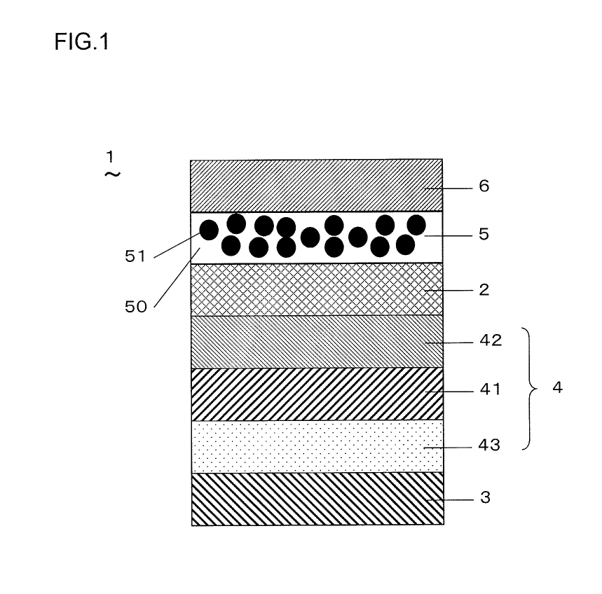

An organic electroluminescence element (abbreviated as the organic EL element hereinafter) according to a preferred embodiment of the present invention is described with reference to FIG. 1. An organic EL element 1 of the present preferred embodiment includes an organic layer 4 located between a first electrode layer 2 and a second electrode layer 3, a light extraction layer 5 located on at least one surface of the first electrode layer and the second electrode layer 3 so that directivity of light is changed, and a substrate 6 located on the light extraction layer 5. In the above configuration, the first electrode layer 2 functions as an anode for supplying a hole to a hole transport layer 42, and the second electrode layer 3 functions as a cathode for supplying an electron to a light emitting layer 41. The first electrode layer 2 and the substrate 6 have translucency, and the second electrode layer 3 has light reflectivity. In the present preferred embodiment, the light extraction layer 5 is located on one surface of the first electrode layer 2. In the organic EL element 1 having such a configuration, when a voltage is applied between the first electrode layer 2 and the second electrode layer 3, light generated by the light emitting layer 41 of the organic layer 4 passes through the first electrode layer 2 and the substrate 6 and then is taken out from the element.

In the present preferred embodiment, in addition to the light emitting layer 41 which includes a light emitting material, the organic layer 4 has an electron transport layer 43 located between the second electrode layer 3 and the light emitting layer 41 and a hole transport layer 42 located between the first electrode layer 2 and the light emitting layer 41, however, the present invention is not limited to the above configuration. Moreover, the light emitting layer 41 may have a laminated structure made up of plural light emitting layers.

A transparent glass plate such as a soda-lime glass, a non-alkali glass, or the like or a plastic film or a plastic plate, which is made from polyester resin, polyolefin resin, polyamide resin, epoxy resin, fluorine contained resin, or the like by an optional method, for example, is used for the substrate 6. The substrate 6 may be made of glass into which a heavy metal such as lead, for example, is mixed, and an optional glass may be used.

The light extraction layer 5 is formed of a composition in which a light-scattering particle 51 of 1-5 wt. % of a base material 50 is mixed into the base material 50, which constitutes the light extraction layer 5. A material which has a high level of translucency and also has a refractive index substantially equal to that of the first electrode layer 2 or the second electrode layer 3, which contacts the light extraction layer 5, is preferably used for the base material 50, and, for example, imide series resin, thiourethane series resin, or the like is used. A translucency microparticle such as silica, alumina, or the like is used for the light-scattering particle 51. When a concentration of the light-scattering particle 51 is lower than 1 wt. %, the light extraction efficiency cannot sufficiently be obtained.

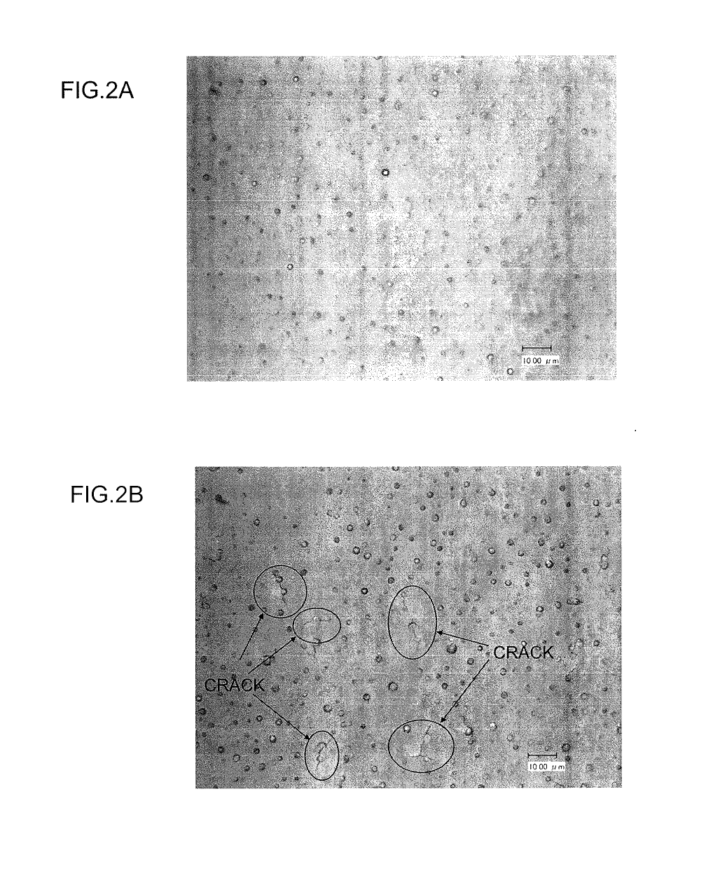

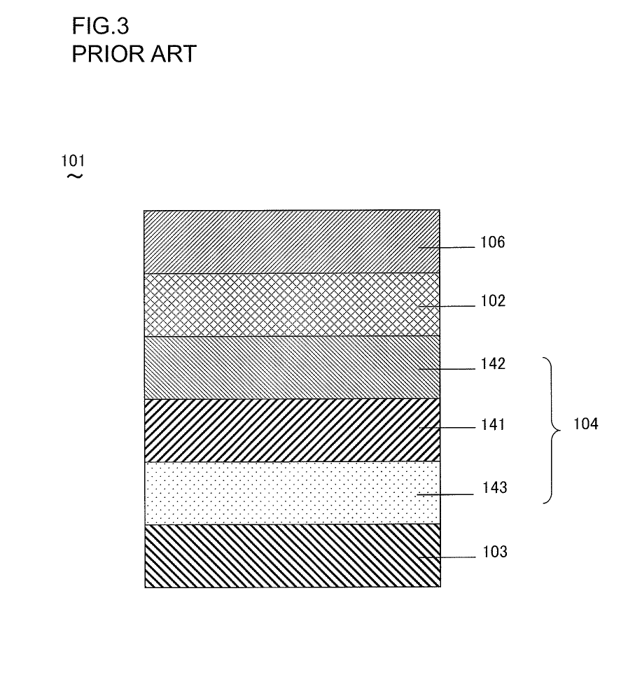

In contrast, when the concentration of the light-scattering particle 51 is higher than 5 wt. %, a crack may occur in the substrate 6 contacting the light extraction layer 5. Each of FIGS. 2A and 2B shows a microscope photograph of a surface of the light extraction layer 5 made by dispersing the light-scattering particle 51 of 5 wt. % and 7.5 wt. % or 10 wt. % of an imide series resin into an imide series resin, which is the base material 50, applying each of them to the glass substrate 6, and drying it. An imide series resin manufactured by OPTMATE Corporation and methyl silicone particles (particle diameter of 2 μm) manufactured by GE Toshiba Silicones Co., Ltd are used for the base material 50 and the light-scattering particle 51, respectively.

As shown in FIG. 2B, when the light extraction layer 5 to which the light-scattering particle 51 of 7.5 wt. % of the base material 50 is added to the base material 50 is applied, the crack is generated on the surface of the substrate 6. This crack causes short-circuit and decreases reliability of a device. In contrast, as shown in FIG. 2A, when the light extraction layer 5 to which the light-scattering particle 51 of 5 wt. % of the base material 50 is added to the base material 50 is applied, the crack is not generated on the surface of the substrate 6.

It is preferable that the particle diameter of the light-scattering particle 51 is 0.05 to 10 μm. When the particle diameter of the light-scattering particle 51 is less than 0.05 μm, the effect of scattering the light cannot sufficiently be obtained, and the light extraction efficiency cannot sufficiently be enhanced. In contrast, when the particle diameter of the light-scattering particle 51 is more than 10 μm, a flatness of a surface of the light extraction layer 5 opposite to the surface which contacts the substrate 6 may deteriorate.

The light-scattering particle 51 may have an isotropic shape such as a spherical shape, however, it is preferable that its shape differs in a long axis direction and a short axis direction. When the light-scattering particle 51 has an anisotropic shape, the light-scattering particles 51 are arranged so that their long axis directions are directed at various angles in various directions with respect to a film thickness direction of the light extraction layer 5, and thus the light scattering effect generated by the light-scattering particle 51 can be enhanced.

When the light extraction layer 5 including the light-scattering particles 51 having the anisotropic shape is applied to and formed on the surface of the substrate 6, the light-scattering particles 51 are arranged so that their long axis directions are not regularly arranged in the same direction parallel to the surface of the substrate 6 but are arranged in irregular directions unless a particular processing or the like is performed. Thus, the light-scattering particle 51 having the anisotropic shape can enhance the light scattering effect in all the directions compared to the light-scattering particle 51 having the spherical shape. Accordingly, when the anisotropic light-scattering particle 51 having the long axis direction and the short axis direction is used for the light extraction layer 5, an obliquely-directed light can be scattered while also reducing the deterioration of the light extracted for a front direction, so that the light extraction efficiency can be further enhanced.

Herein, the long axis direction and the short axis direction of the light-scattering particle 51 need not be perpendicular to each other, however, the light-scattering particle 51 may have the anisotropic shape so that its long axis direction and the short axis direction intersect at an optional angle. Moreover, as described above, it is preferable that the particle diameter of the anisotropic light-scattering particle 51 is within 0.05 to 10 μm in the long axis direction and the short axis direction. It is also preferable that the difference of the particle diameter between the long axis direction and the short axis direction is set so that the particle diameter in the long axis direction is within 1.2 to 5 when the particle diameter in the short axis direction is 1. It is not preferable that the particle diameter in the long axis direction is more than 5 by reason that there is the possibility that the flatness of the surface of the light extraction layer 5 opposite to the surface which contacts the substrate 6 deteriorates.

Moreover, the surface of the light-scattering particle 51 may be flat, however, it is preferable that the light-scatting particle 51 has the irregular configuration. When the surface of the light-scattering particle 51 has the irregular configuration, the light scattering effect can be enhanced compared to the case that the surface is flat, so that the light extraction efficiency can be further enhanced.

A light-scattering particle which has a refractive index smaller than that of the base material 50, which constitutes the light extraction layer 5, is used as the light-scattering particle 51. In this way, the light which enters the base material 50 can be totally reflected on the surface of the light-scattering particle 51 and scattered in the various directions.

It is preferable that the difference of the refractive index between the base material 50 constituting the light extraction layer 5 and the light-scattering particle 51 is within 0.15 to 0.45. When the difference is less than 0.1, the light which is totally reflected on the surface of the light-scattering particle 51 is reduced, and the sufficient light-scattering function cannot be obtained. In view of the fact that the refractive index of the translucent resin used as the base material 50 is normally around 1.4 to 1.8, it is not easy to use a very low refractive index material, whose refractive index difference with the base material 50 is 0.45 or more, for the light-scattering material 51.

Moreover, it is preferable that light transmissibility of the light extraction layer 5 is at least 50% or more, and 80% or more is more preferable. Moreover, it is preferable that the light extraction layer 5 is designed to prevent the total reflection at an interface between the light extraction layer 5 and the first electrode layer 2. That is to say, it is preferable that the refractive index of the base material 50 of the light extraction layer 5 is substantially equal to that of the first electrode layer 2. The above term “substantially equal” indicates that the refractive index difference is ±0.2 or less.

It is preferable that an electrode material made up of a metal, an alloy, or an electrically-conductive compound having a high work function, or a mixture thereof is used for the first electrode layer 2 so that the hole can be efficiently injected into the organic layer 4, and it is particularly preferable that an electrode material having a work function of 4 eV or more is used. Such a material of the first electrode layer 2 includes, for example, a metal such as gold, CuI, ITO (Indium Tin Oxide), SnO₂, ZnO, IZO (Indium Zinc Oxide), GZO (Gallium Zinc Oxide), a conductive polymer such as PEDOT or polyaniline, a conductive polymer doped with an optional acceptor, or a conductive translucent material such as carbon nanotubes. The first electrode layer 2 can be made by depositing the above electrode material on the surface of the substrate 6 by a vacuum evaporation method, a sputtering method, a coating method, for example, to form a thin film. It is preferable that light transmissibility of the second electrode layer 3 is 70% or more. Moreover, it is preferable that sheet resistance of the second electrode layer 3 is several hundred Ω/□ or less, and 100Ω/□ or less is more preferable. Although the film thickness of the first electrode layer 2 differs depending on characteristics such as conductivity of the material, the film thickness is preferably set to 500 nm or less to control the characteristics such as the light transmissibility, the sheet resistance, or the like of the first electrode layer 2 as described above, and is more preferably set within a range of 10 to 200 nm. Moreover, it is preferable that the surface of first electrode layer 2 opposite to the surface which contacts the light extraction layer 5 has high flatness to prevent a leak current or a short circuit.

The organic layer 4 is made up of a lamination of the above hole transport layer 42, the light emitting layer 41, and the electron transport layer 43, and an appropriate organic layer such as an electron transport layer, a hole block layer, an electron injection layer, or the like (not shown) may also be laminated on the light emitting layer 41. Moreover, a plurality of the light emitting layers 41 may also be formed. In this manner, when the plural light emitting layers 41 are provided, the number laminated layers is preferably five or less and more preferably three or less since difficulty in design of an optical and electrical element increases with increasing the number of laminated layers. Moreover, in this case, it is preferable to provide a charge supply layer (not shown) between the plural organic layers 4. This charge supply layer includes, for example, a metal thin film such as Ag, Au, or Al, a metal oxide such as vanadium oxide, molybdenum oxide, rhenium oxide, or tungsten oxide, a transparent conductive film such as ITO, IZO, AZO, GZO, ATO, or SnO₂, a so call laminated body of a n-type semiconductor and a p-type semiconductor, a laminated body of the metal thin film or the transparent conductive film and the n-type semiconductor and/or the p-type semiconductor, a mixture of the n-type semiconductor and the p-type semiconductor, or a mixture of the n-type semiconductor or the p-type semiconductor and the metal. The n-type semiconductor or the p-type semiconductor may be made of an inorganic material or an organic material. Further, it may also be made of a combination of a mixture of the organic material and the metal, the organic material and the metal oxide, the organic material and the organic acceptor/donor material, or the inorganic acceptor/donor material, for example, and these are appropriately selected and used.

A material of the hole transport layer 42 is appropriately selected from a group of compounds having a characteristic of hole transport. This type of compounds includes, for example, a triarylamine-based compound, an amine compound including a carbazole group, an amine compound including fluorene derivative, or the like whose representative examples are 4,4′-Bis[N-(naphthyl)-N-phenylamino]biphenyl (α-NPD), N,N′-Bis(3-methylphenyl)-(1,1′-biphenyl)-4,4′-diamine (TPD), 2-TNATA, 4,4′,4″-tris[N-(3-methylphenyl)N-phenylamino]triphenylamine (MTDATA), 4,4′-N,N′-dicarbazole-biphenyl (CBP), Spiro-NPD, Spiro-TPD, Spiro-TAD, or TNB. The material is not limited to the above, however, a commonly-known optional hole transport material may be used.

The organic EL material constituting the light emitting layer 41 includes a material series and its derivative such as, for example, anthracene, naphthalene, pyrene, tetracene, coronene, perylene, phthaloperylene, naphthaloperylene, diphenylbutadiene, tetraphenylbutadiene, coumarin, oxadiazole, bisbenzoxazorine, bisstyryl, cyclopentadiene, quinoline metal complex, tris(8-hydroxyquinolinate)aluminum complex (Alq₃), tris(4-methyl-8-quinolinate)aluminum complex, tris(5-phenyl-8-quinolinate)aluminum complex, aminoquinoline metal complex, benzoquinoline metal complex, tri(p-terphenyl-4-yl)amine, 1-aryl-2,5-di(2-thienyl)pyrrole derivative, pyrane, quinacridone, rubrene, distyrylbenzene derivative, distyrylarylene derivative, distyrylamine derivative, or various fluorescent dyes, however, the organic EL material is not limited to the above materials. It is preferable to use an appropriate mixture of the emitting material optionally selected from these compounds. In addition to the compounds derived from fluorescent dyes typified by the above compounds, so-called phosphorescence emitting materials, for example, a light emitting material such as an Ir complex, an Os complex, a Pt complex, or a europium complex, or compounds or polymers having these materials within the molecules can also be preferably used. These materials are appropriately selected and used as necessary. The light emitting layer 41 made up of the above materials may be formed by a dry process such as deposition or transfer, or may be formed by a wet process such as spin coating, spray coating, die coating, or gravure printing.

The electron transport layer 43 is formed from a material appropriately selected from a group of compound having an electron transport property. This type of compound includes a metal complex known as the electron transport material such as Alq₃, a compound having a hetero ring such as phenanthroline derivative, pyridine derivative, tetrazine derivative, or oxadiazole derivative, or the like. The material is not limited to the above, however, a commonly-known optional electron transport material may be used.

It is preferable that a metal, an alloy, an electroconductive compound, or a mixture of the above materials having a low work function is used for the second electrode layer 3 so as to efficiently inject the electrons into the light emitting layer 41, it is particularly preferable that the work function is 5 eV or less. The material such as an alkali metal, an alkali metal halide, an alkali metal oxide, an alkali earth metal, or an alloy of the above materials and other metal, for example, is used to constitute the second electrode layer 5 (sic. correctly 3). In particular, Aluminum (Al), silver (Ag), or a compound including these metals may be used. Moreover, the second electrode layer 3 may also be made as a laminated structure of combining Al and the other electrode material. The combination of the electrode material includes a laminated body of an alkali metal/Al, alkali metal/silver, alkali metal halide/Al, alkali metal oxide/Al, alkali earth metal/Al, rare-earth metal/Al, an alloy of these metallic series and other metal, or the like. In particular, it includes, for example, sodium (Na), sodium-pottasium (K) alloy, lithium (Li), a laminated body of magnesium (Mg) or the like and silver, Mg—Ag mixture, Mg-indium mixture, Al—Li alloy, LiF/Al mixture/laminated body, or Al/Al₂O₃ mixture. Moreover, the electrode material may be made by laminating at least one layer of a conductive material such as a metal or the like on a ground, which is made of an alkali metal oxide, an alkali metal halide, or a metal oxide, of the second electrode layer 3. The laminated conductive material is an alkali metal/Al, an alkali metal halide/alkali earth metal/Al, an alkali metal oxide/Al, or the like. Moreover, also as for the other laminated conductive material other than the above laminated conductive materials, it is preferable to insert a layer which enhances the injection of the electrons from the second electrode layer 3 (cathode) into the light emitting layer 41, that is to say, an electron injection layer (not shown) between the cathode and the light emitting layer. A material constituting the electron injection layer includes, for example, a material in common with that of the above second electrode layer 3, a metal oxide such as titanic oxide, zinc oxide, or the like, an organic semiconductor material in which a dopant, which enhances the electron injection like the above materials, is mixed, however, the material is not limited to the above.

The second electrode layer 3 may also be formed of a combination of a transparent electrode and a light reflection layer. When the second electrode layer 3 is formed as a translucent electrode, it may be formed of the transparent electrode typified by ITO, IZO, or the like. The organic layer at an interface of the second electrode layer 3 may be doped with an alkali metal or an alkali earth metal such as lithium, sodium, cesium, calcium, or the like.

The manufacturing method of the second electrode layer 3 includes the vacuum evaporation method, the sputtering method, the coating method, for example, to form a thin film using the above electrode material. When the second electrode layer 5 (sic. correctly 3) is the light-reflective electrode, the reflectivity is preferably 80% or more and is more preferably 90% or more.

When the second electrode layer 3 is the translucent electrode, it is preferable that the light transmissibility of the second electrode layer 3 is 70% or more. In this case, although a film thickness of the second electrode layer 5 (sic. correctly 3) differs depending on the material, it is preferably set to 500 nm or less to control the characteristics such as the light transmissibility or the like of the second electrode layer 5 (sic. correctly 3), and it is particularly preferable that it is set within a range of 100 to 200 nm.

### WORKING EXAMPLE

Next, a working example of the above preferred embodiment is particularly described by comparing the working example with a comparison example.

### Working Example 1

Firstly, methyl silicone particles (particle diameter of 2 μm, manufactured by GE Toshiba Silicones Co., Ltd, Tospearl 120, nD=1.45) are added as the light-scattering particle 51 to an imide series resin (manufactured by OPTMATE Corporation, HR11783, nD=1.78, 18% concentration) as the base material 50 of the light extraction layer 5 so that the methyl silicone particles are set to 5 wt % of the imide series resin and are subsequently dispersed by a homogenizer to obtain a coating material composition.

Next, an alkali-free glass (No. 1737; Corning Incorporated) of 0.7 mm thickness is used as the substrate 6, the obtained coating material composition is applied to a surface of the glass by a spin coater at 1000 rpm, dried, and thermally-processed by baking at 200 degrees Celsius for 30 minutes, and the light extraction layer 5 of appropriately 6.5 μm thickness is provided.

Next, a sputtering is performed using ITO (Indium Tin Oxide) target (manufactured by TOSOH CORPORATION), and an ITO film of 150 nm thickness is formed. The glass substrate on which the obtained ITO layer is laminated is annealed under Ar atmosphere at 200 degrees Celsius for one hour, and the first electrode 2 which has the sheet resistance of 18Ω/□ is formed. The refractive index of the first electrode 2 is nD=1.78 when measured by an optical thin film measuring system SCI3000 FilmTek manufactured by Scientific Computing International.

An ultrasonic cleaning is performed on the above glass substrate with pure water, acetone, and isopropyl alcohol for ten minutes, respectively, and subsequently, a vapor washing is performed on the glass substrate with isopropyl alcoholic vapor for two minutes. Then, the glass substrate is dried and an UV ozone cleaning is performed for ten minutes. Subsequently, the glass substrate is set in a vacuum evaporation apparatus, and 4,4′-bis[N-(naphthyl)-N-phenyl-amino]biphenyl(α-NPD) is evaporated under reduced pressure of 5×10−5 Pa so as to have a thickness of 40 nm, and the hole transport layer 42 is formed on the first electrode layer 2 (ITO). Subsequently, the light emitting layer 41 made up of Alq3 doped with 6% of rubrene is provided on the hole transport layer 42 so as to have a thickness of 30 nm. Moreover, TpPyPhB is deposited as the electron transport layer 43 so as to have a thickness of 65 nm. Furthermore, LiF is deposited as the electron injection layer (not shown) so as to have a thickness of 1 nm, and Al is deposited as the second electrode layer 3 (cathode) so as to have a thickness of 80 nm, and accordingly, the organic EL element 1 of the working example 1 is made.

### Working Example 2

The organic EL element 1 of the working example 2 is made in the same manner as the working example 1 except that an acrylic resin particle (manufactured by SEKISUI PLASTICS CO., Ltd., L-XX-03N, average particle diameter of 5 μm, nD=1.5) having convex lens shape is used as the light-scattering particle 51.

### Working Example 3

The organic EL element 1 of the working example 3 is made in the same manner as the working example 1 except that a surface asperity microparticle (manufactured by Matsumoto Yushi-Seiyaku Co., Ltd, Matsumoto microsphere M, particle diameter of 5 μm, nD=1.5) is used as the light-scattering particle 51.

### Comparison Example 1

803.5 g of isopropyl alcohol is added to 86.8 g of tetraethoxysilane and moreover, 34.7 g of γ-methacryloxypropyl trimethoxy silane and 75 g of 0.1N nitric acid are added, and they are mixed well using an agitator to adjust the constituent humor. The adjusted constituent humor is agitated in a constant temperature reservoir of 40° C., and silicone resin solution (nD=1.43) of silicon resin 5 mass % as a binder formation material whose weight-average molecular weight is 1050 is obtained. The methyl silicone particles (particle diameter of 2 μm, manufactured by GE Toshiba Silicones Co., Ltd, Tospearl 120, nD=1.45) are added to the silicone resin solution so that a solid content mass ratio of the methyl silicone particle and the silicon resin is set to 80:20 (condensation compound conversion), and they are dispersed by the homogenizer to obtain methyl silicon particle dispersion silicone resin solution. “Condensation compound conversion” indicates a mass when an existing Si is SiO₂ in case of tetraalkoxysilane and a mass when an existing Si is SiO_{1.5} in case of trialkoxysilane.

Next, an alkali-free glass (No. 1737; Corning Incorporated) of 0.7 mm thickness is used as the substrate 6, the obtained coating material composition is applied to a surface of the glass by a spin coater at 1000 rpm and dried. After repeating application and drying six times, it is thermally-processed by baking at 200 degrees Celsius for 30 minutes.

Next, in order to provide a flatness to the light extraction layer, an imide series resin (manufactured by OPTMATE Corporation, HR11783, nD=1.78, 18% concentration) is applied to the glass substrate provide with the scattering particle layer by a spin coater at 2000 rpm and dried to form a film, and subsequently, it is thermally-processed by baking at 200 degrees Celsius for 30 minutes and a flatness layer of approximately 4 μm thickness is laminated. The organic EL element 1 of the comparison example 1 is obtained in the same manner as the working example 1 except that the light extraction layer is made by the above procedure.

(Evaluation Test)

In the organic EL element made as the respective working examples and the comparison example, an electrical current having current density of 10 mA/cm² is applied between the electrodes, and the light which is emitted to the atmosphere is measured using an integrating sphere. Respective external quantum efficiencies are calculated on the basis of the measuring result, and ratios of the external quantum efficiencies to the comparison example 1 is shown in a table 1 below.

TABLE 1

| | Ratio of external quantum efficiency |
|---|---|
| Working Example 1 | 1.04 |
| Working Example 2 | 1.14 |
| Working Example 3 | 1.08 |
| Comparison Example 1 | 1.00 |

As shown in the above table 1, in the working examples 1 to 3 based on the above preferred embodiment, it is indicated that the external quantum efficiency is enhanced compared to that of the comparison example 1. In the working examples 1 to 3, the light extraction layer 5 is a single layer. That is to say, since the light extraction layer 5 is made up of the base material 50 and the light-scattering particle 51 of 5 wt. % of the base material 50, the gap at the interface between the base material 50 and the light-scattering particle 51 is difficult to form, thus a loss of the light due to the gap is suppressed and the light extraction efficiency can be enhanced. Although not described in the above table 1, when the light-scattering particle 51 of 1 wt. % or more of the base material 50 is added, the enhancement of the light extraction efficiency is confirmed.

In the working examples 1 to 3, the flatness layer is not formed on the light extraction layer 5, however, the external quantum efficiency higher than that of the comparison example 1, in which the flatness layer is formed, is indicated. This result shows that when the particle diameter of the light-scattering particle (substantially 0.1 to 10 μm) is small, the unevenness of the surface facing with the first electrode layer 5 (or the second electrode layer 3) can be made small in the light extraction layer 5, so that light emission equal to or larger than the case that there is the flatness layer can be achieved. Moreover, when the unevenness of the surface of the light extraction layer 5 (sic. correctly 2) is small, the evenness and the uniform thickness of the first electrode layer 5 (sic. correctly 2), which is foamed on the light extraction layer 5, can also be achieved. As a result, the possibility of the short circuit of the element can be reduced, and reliability of a device using this organic EL element 1 can be enhanced.

Moreover, in the working example 2, the external quantum efficiency higher than that of the working example 1 is indicated. This result shows that when the light-scattering particle 51 having the anisotropic shape (the acrylic resin particle convex lens shape) is used, as shown in the working example 2, the light scattering effect can be enhanced and the light extraction efficiency can further be enhanced. Moreover, in the working example 3, the external quantum efficiency higher than that of the working example 1 is indicated. This result shows that when the light-scattering particle 51 having the irregular shape is used, as shown in the working example 3, the light scattering effect can be enhanced and the light extraction efficiency can further be enhanced.

Moreover, in the working examples 1 to 3, the difference between the refractive index of the base material 50 constituting the light extraction layer 5 and the light-scattering particle 51 is 0.15 or more, and in contrast, the refractive index difference in the comparison example 1 is less than 0.15. The working examples 1 to 3 indicate the external quantum efficiency higher than that of the comparison example 1. This result shows that the preferable light-scattering property can be obtained by the light-scattering particle 51 by the difference of the refractive index difference.

Furthermore, when the refractive index of the base material 50 constituting the light extraction layer 5 and the refractive index of the first electrode layer 2 (anode) is substantially equal to each other, so that the light passing through the first electrode layer 2 is not totally reflected at the interface between the first electrode layer 2 and the light extraction layer 5 but enters the light extraction layer 5 and thus can be scattered by the light-scattering particle 51.

The present invention is not limited to the configuration of the above preferred embodiment, however, various modification are applicable as long as the light extraction layer 5 which includes the light-scattering particle 51 of 1 to 5 wt. % of the base material 50 is provided on at least one of the surfaces of the first electrode layer 2 and the second electrode layer 3. For example, a material other than the light-scattering particle 51 may be added to the base material 50 constituting the light extraction layer 5. Moreover, a layer which is made in the same manner as the above light extraction layer 5 may be provided outside of the substrate 6.

The present application is based on Japanese Patent Application 2011-083316, and the content there of is incorporated herein by reference to the specification and the drawings of the above patent application.

### DESCRIPTION OF THE NUMERALS

1 organic EL element

2 first electrode layer

3 second electrode layer

4 organic layer

5 light extraction layer

50 base material

51 light-scattering particle

6 substrate

1. An organic electroluminescence element, comprising:
an organic layer which is located between a first electrode layer and a second electrode layer;
a light extraction layer which is located on at least one surface of the first electrode layer and the second electrode layer so that directivity of light is changed; and
a substrate located on the light extraction layer, wherein
the light extraction layer has a base material which constitutes the light extraction layer and a light-scattering particle of 1 to 5 wt. % of the base material.

2. The organic electroluminescence element according to claim 1, wherein
a particle diameter of the light-scattering particle is 0.1 to 10 μm.

3. The organic electroluminescence element according to claim 1, wherein
the light-scattering particle is a particle whose shape differs in a long axis direction and a short axis direction.

4. The organic electroluminescence element according to claim 1, wherein
the light-scattering particle has an irregular configuration on its surface.

5. The organic electroluminescence element according to claim 1, wherein
a difference between a refractive index of the base material constituting the light extraction layer and a refractive index of the light-scattering particle is 0.15 to 0.45.

6. The organic electroluminescence element according to claim 1, wherein
a refractive index of the base material constituting the light extraction layer and a refractive index of the first electrode layer or the second electrode layer contacting the light extraction layer is substantially equal to each other.

7. The organic electroluminescence element according to claim 1, wherein
the light-scattering particle has a refractive index smaller than that of the base material.
